(19) United States
(12) Patent Application Publication
(10) Pub. No.: US 2011/0017590 A1
(43) Pub. Date: Jan. 27, 2011

(54) Sintered Compact Target and Method of Producing Sintered Compact

(75) Inventors: Hideaki Fukuyo, Ibaraki (JP); Masataka Yahagi, Ibaraki (JP); Yasuhiro Yamakoshi, Ibaraki (JP); Hideyuki Takahashi, Ibaraki (JP)

Correspondence Address: HOWSON & HOWSON LLP, 501 OFFICE CENTER DRIVE, SUITE 210, FORT WASHINGTON, PA, 19034, US

(73) Assignee: JX NIPPON MINING & METALS CORPORATION, Tokyo (JP)

(21) Appl. No.: 12/922,485

(22) PCT Filed: Dec. 9, 2008
(86) PCT No.: PCT/JP2008/072296

§ 371 Date: Sep. 14, 2010

(30) Foreign Application Priority Data
Mar. 17, 2008 (JP) 2008-067317
Apr. 23, 2008 (JP) 2008-112652

(51) Int. Cl. C23C 14/34; B22F 3/11

(52) U.S. Cl. 204/298.13; 419/2; 977/773

(57) ABSTRACT

Disclosed is a sintered compact target containing an element (A) and an element (B) below, wherein the sintered compact target is free from pores having an average diameter of 1 μm or more, and the number of micropores having an average diameter of less than 1 μm existing in 40000 μm² of the target surface is 100 micropores or less:

(A): one or more chalcogenide elements selected from S, Se, and Te; and (B): one or more Vb group elements selected from Bi, Sb, As, P, and N.

The provided technology is able to eliminate the source of grain dropping or generation of nodules in the target during sputtering, and additionally inhibit the generation of particles.

### TECHNICAL FIELD

The present invention relates to a method of producing a sintered compact target capable of reducing minute defects within the sintered compact and having high deflecting strength, and containing a Vb group element (A) and a chalcogenide element (B) or containing the elements (A), (B) and one or more elements from a IVb group element (C) or an additive element (D).

### BACKGROUND ART

In recent years, a thin film formed from a Ge—Sb—Te base material is being used as a material for use in phase change recording; that is, as a medium for recording information by using phase transformation.

As a method of forming this thin film formed from the Ge—Sb—Te base alloy material, a means generally referred to as a physical vapor deposition method such as the vacuum deposition method or the sputtering method are commonly used. Especially, the magnetron sputtering method is used for its operability and film stability.

Formation of films by way of the sputtering method is performed by physically colliding positive ions such as Ar ions to a target disposed on a cathode, using that collision energy to discharge materials configuring the target, and laminating a film having roughly the same composition as the target material on the opposite anode-side substrate.

The coating method based on the sputtering method is characterized in that it is possible to form films of various thicknesses; for instance, from a thin film of angstrom units to a thick film of several ten pm, with a stable deposition speed by adjusting the processing time, power supply and the like.

Conventionally, in order to inhibit the generation of particles that occurs in the sputtering process, a high density sintered compact having a relative density of approximately 98.8% was prepared by sintering, via hot press, raw material powder having high purity and a prescribed grain size.

A sintered compact that is sintered by combining a chalcogenide element (S, Se, Te), a Vb group element (Bi, Sb, As, P, N), and additional a IVb group element (Pb, Sn, Ge, Si, C) and an additive element (Ag, Au, Pd, Pt, B, Al, Ga, In, Ti, Zr) generally has low thermal conductivity.

If there are minute defects (micropores: gaps of less than 1 μm that appear at the grain boundary portion) in this kind of sintered compact having low thermal conductivity, since the dispersion of heat is inhibited by the defects, heat will remain at the periphery thereof, and components (for instance, GeTe₂) having high vapor pressure will be volatilized from such portion.

Meanwhile, the remaining portion will take on a crater shape and become an abnormally eroded portion. The surface structure of a target having the foregoing defects will become the source of causing grain dropping or generating nodules, and additionally cause a major problem in that particles are generated easily.

As conventional technology, there is a method of producing a sputtering target of phase-change ZnS and SiO₂ having a relative density of 98% or higher by using HIP (hot isostatic pressing) and performing the treatment at a temperature of 1000° C. or higher and a pressure of 100 MPa or more (refer to Patent Document 1).

Nevertheless, in the foregoing case, if the HIP process of pressurizing the product using high-pressure Ar gas alone is performed, there is a drawback in that it is not possible to obtain a dense sintered compact that can be obtained with the vacuum hot press method of advancing the sintering process while eliminating the gas generated from the product, since there will always be gas at the periphery thereof.

### [Patent Document 1] Japanese Patent Laid-Open Publication No. 2000-26960

### DISCLOSURE OF THE INVENTION

### Problems Which the Invention Intends to Solve

The present invention provides a sintered compact target capable of reducing minute defects within the sintered compact and having high deflecting strength, and containing a Vb group element (A) and a chalcogenide element (B) or containing the elements (A), (B) and one or more elements from a IVb group element (C) or an additive element (D), and a method of producing such a sintered compact target, and additionally provides technology that is able to eliminate the source of grain dropping or generation of nodules in the target during sputtering, and additionally inhibit the generation of particles. This is groundbreaking technology of being able to form a low-oxygen sintered compact while initially eliminating unnecessary gas components based on vacuum hot press from the Sb—Te alloy such as GST in which pores caused by insufficient sintering due to the oxidation of the powder surface are easily formed, and further completely crushing and eliminating the remaining minute pores.

The present invention can be applied to both pulverized powder having an average grain size of approximately 30 μm and fine powder having an average grain size of less than 3 μm. In addition, although there are cases where the grains mutually become cross-linked due to necking during hydrogen reduction, and the gaps thereof remain as pores, if the present technology is employed, the pores can be eliminated completely, and it is also possible to produce a low-oxygen product.

In addition, it is possible to produce a high density, high strength and large diameter sintered compact target, and the present invention provides a sintered compact containing a chalcogenide element (A) and a Vb group element (B) or containing the element (A), (B) and one or more elements from a IVb group element (C) or an additive element (D) which is free from cracks even when assembled and used as a sputtering target-backing plate assembly, as well as a method of producing such a sintered compact.

### Means for Solving the Problems

As a result of devising the sintering conditions, the present inventors discovered that the foregoing problems can be solved.

Based on the foregoing discovery, the present invention provides:

1. A sintered compact target containing an element (A) and an element (B) below, wherein the sintered compact target is free from pores having an average diameter of 1 μm or more, and the number of micropores having an average diameter of 0.1 to 1 μm existing in an area of 40000 μm² of the target surface is 100 micropores or less, more preferably 10 or less:
(A): one or more chalcogenide elements selected from S, Se, and Te
(B): one or more Vb group elements selected from Bi, Sb, As, P, and N
2. A sintered compact target containing an element (A), an element (B) and one or more elements selected from (C) or (D) below, wherein the sintered compact target is free from pores having an average diameter of 1 μm or more, and the number of micropores having an average diameter of 0.1 to 1 μm existing in an arbitrarily selected area of 40000 μm² of the target surface is 100 micropores or less, more preferably 10 or less:
(A): one or more chalcogenide elements selected from S, Se, and Te
(B): one or more Vb group elements selected from Bi, Sb, As, P, and N
(C): one or more IVb group elements selected from Pb, Sn, Ge, Si, and C
(D): one or more elements selected from Ag, Au, Pd, Pt, B, Al, Ga, In, Ti, and Zr

The present invention additionally provides:

3. The sintered compact target according to paragraph 1 or paragraph 2, wherein the element (A) is Te, the element (B) is Sb, the element (C) is Ge, and the element (D) is one or more elements selected from Ag, Ga, and In;
4. The sintered compact target according to paragraph 3, wherein the sintered compact target is one among Ge—Sb—Te, Ag—In—Sb—Te, and Ge—In—Sb—Te;
5. The sintered compact target according to any one of paragraphs 1 to 4, wherein the average crystal grain size of the structure of the sintered compact target is 50 μm or less, the deflecting strength is 40 MPa or more, the relative density is 99% or higher, the standard deviation of the relative density is 1%, and the variation in the composition of the respective crystal grains configuring the target is less than ±20% of the overall average composition; and
6. The sintered compact target according to paragraph 5 above, wherein the average crystal grain size is 10 μm or less.

The present invention further provides:

7. A method of producing a sintered compact containing an element (A) and an element (B) below, including the steps of mixing raw material powder composed of the respective elements or raw material powder of an alloy of two or more elements, and vacuum hot press the mixed powder under conditions that satisfy the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), and further performing HIP treatment under the conditions of Pₕᵢₚ>5×Pf, wherein the sintered compact is free from pores having an average diameter of 1 μm or more, and the number of micropores having an average diameter of less than 1 μm existing in an area of 40000 μm² of the target surface is 100 micropores or less, more preferably 10 or less:
(A): one or more chalcogenide elements selected from S, Se, and Te
(B): one or more Vb group elements selected from Bi, Sb, As, P, and N
8. A method of producing a sintered compact containing an element (A), an element (B) and one or more elements selected from (C) or (D) below, including the steps of mixing raw material powder composed of the respective elements or raw material powder of an alloy of two or more elements, and vacuum hot press the mixed powder under conditions that satisfy the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), and further performing HIP treatment under the conditions of Pₕᵢₚ>5×Pf, wherein the sintered compact is free from pores having an average diameter of 1 μm or more, and the number of micropores having an average diameter of 0.1 to 1 μm existing in an area of 40000 μm² of the target surface is 100 micropores or less:
(A): one or more chalcogenide elements selected from S, Se, and Te
(B): one or more Vb group elements selected from Bi, Sb, As, P, and N
(C): one or more IVb group elements selected from Pb, Sn, Ge, Si, and C
(D): one or more elements selected from Ag, Au, Pd, Pt, B, AI, Ga, In, Ti, and Zr

The present invention also provides:

9. The method of producing a sintered compact according to paragraph 7 or paragraph 8 above, wherein sintering is performed by using raw material powder in which the element of is Te, the element of (B) is Sb, the element (C) is Ge, and the element (D) is one or more elements selected from Ag, Ga, and In.
10. The method of producing a sintered compact according to paragraph 9, wherein the sintered compact is one among Ge—Sb—Te, Ag—In—Sb—Te, and Ge—In—Sb—Te.
11. The method of producing a sintered compact according to any one of paragraphs 7 to 10 above, wherein sintering is performed by using raw material powder of elements constituting the sintered compact in which the raw material powder is composed of an alloy, a compound or a mixture of constituent elementary substances or constituent elements, and the average grain size is 0.1 μm to 50 μm, the maximum grain size is 90 μm or less, and the purity is 4N or higher.
12. The method of producing a sintered compact according to any one of paragraphs 7 to 11, wherein, in the course of heating temperature T rising from 100 to 500° C. during the hot press, the pressure is maintained at a constant level for 10 to 120 minutes at least in a part of the heating temperature range.

### Effect of the Invention

Conventionally, when producing a sintered compact target using raw material powder containing a chalcogenide element (A) and a Vb group element (B) or raw material powder containing a IVb group element (C) or an intended additive element (D) added thereto, numerous defects of micropores would exist and become the source of grain dropping and nodules, which is a major cause of the generation of particles during sputtering deposition. The present invention discovered that defects of micropores and the like are a major cause of the generation of particles, and offers a method of considerably reducing the defects of such micropores from the sintered compact target.

Since the sintered compact having the composition of the present invention is extremely fragile, if a large diameter sputtering target is prepared and bonded with a backing plate, there was a problem in that cracks would occur on the target surface or the target itself would crack due to the difference in thermal expansion. Nevertheless, the present invention is able to produce a high strength, high density and large diameter sintered compact or sputtering target capable of considerably reducing defects such as micropores by improving the production process.

The present invention yields a superior effect of preventing the generation of cracks and the like even when the target is bonded to a backing plate, and also keep the warping to be within a tolerable range.

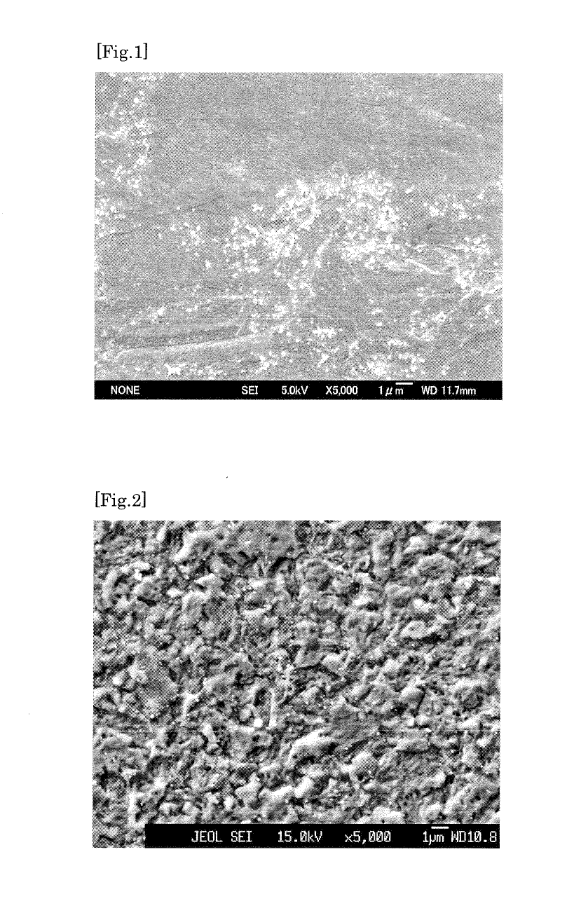

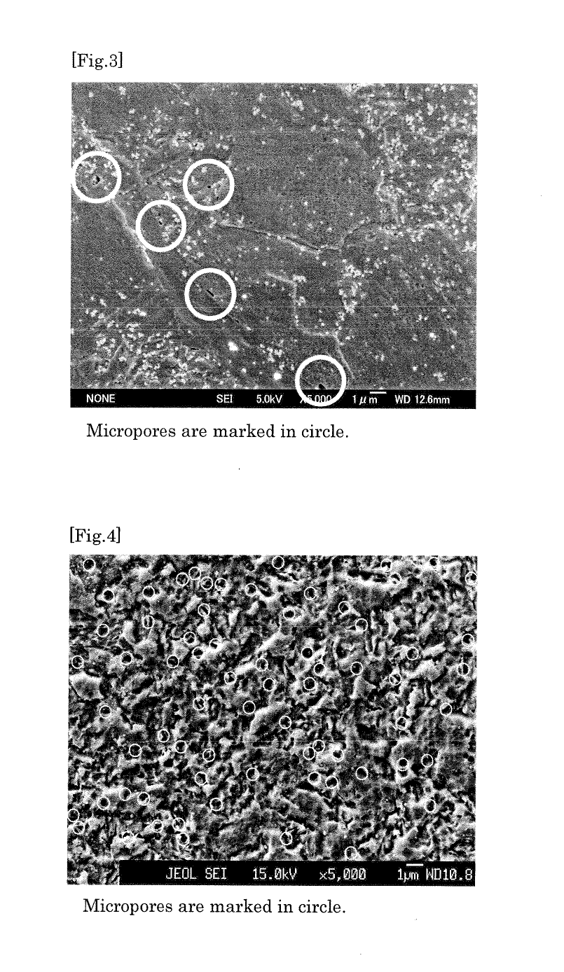

### BRIEF DESCRIPTION OF THE DRAWINGS

[FIG. 1] a 5000× microphotograph upon observing the target structure of Example 1

[FIG. 2] a 5000× microphotograph upon observing the target structure of Example 2

[FIG. 3] a 5000× microphotograph upon observing the target structure of Comparative example 1

[FIG. 4] a 5000× microphotograph upon observing the target structure of Comparative Example 5

### BEST MODE FOR CARRYING OUT THE INVENTION

(Sintering raw material and control of pressure rise and temperature rise conditions of hot press)

As described above, upon producing a sintered compact, the following steps are performed; namely, mixing raw material powder composed of the respective elements or raw material powder of an alloy of two or more elements, and vacuum hot pressing the mixed powder under conditions that satisfy the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius):

(A): one or more chalcogenide elements selected from S, Se, and Te
(B): one or more Vb group elements selected from Bi, Sb, As, P, and N

In addition, the following element (C) or element (D) is added, as needed.

(C): one or more IVb group elements selected from Pb, Sn, Ge, Si, and C
(D): one or more elements selected from Ag, Au, Pd, Pt, B, Al, Ga, In, Ti, and Zr

Consequently, produced is a sintered compact containing a chalcogenide element (A) and a Vb group element (B), or a sintered compact containing a chalcogenide element (A), a Vb group element (B) and one or more elements from a IVb group element (C) or additive element (D).

Controlling the pressure rise and temperature rise conditions of the hot press in a vacuum as described above is an important and basic process, and is achieved by relatively and gradually increasing the pressure P in relation to the temperature T in the course of the temperature rise.

When deviating from these conditions, it becomes difficult to effectively inhibit the generation of defects such as micropores, and it is also virtually impossible to produce a large diameter sintered compact or sputtering target having high strength and high density.

With the foregoing vacuum hot press, the material of the present invention which is easily oxidized can be sintered in a low-oxygen state. In addition, it is also possible to simultaneously prevent the inclusion of unwanted gas components.

The sintered compact target obtained based on the production method of the present invention is able to considerably reduce the defects of micropores and the like. In addition, a large diameter sputtering target having a mechanically high strength is able to inhibit and improve the particle generation rate of a conventional target having a diameter of approximately 300 mm. This is because the grain boundary of the sintered compact has been strengthened based on the fine uniform crystal structure that is free from pores. This can only be achieved based on the foregoing condition of the present invention.

One of the essential basic conditions for achieving the present invention is to perform hot pressing under conditions that satisfy P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), but it is effective to stabilize the pressure for 10 to 120 minutes in the course of the temperature T rising from 100 to 500° C.

By devising the sintering conditions; that is, by combining hot press and HIP, it is possible to produce a low-oxygen, high density sintered compact that is free from micropores.

HIP is performed under the same achieving temperature condition as the hot press, and under the condition of P_{HIP}>5×Pf. HIP is able to completely eliminate the micropores that are remaining internally. The HIP treatment is an important requirement for achieving the number of micropores having an average diameter of 0.1 to 1 μm existing in an area of 40000 μm² on the target surface to be 10 micropores or less, and even 1 micropore or less.

Preferably, the content of oxygen as an impurity is kept 2000 ppm or less. The inclusion of gas components in excess of the foregoing value will cause the generation of a nonconductor such as oxides. Thus, the reduction of oxygen will prevent arcing and thereby inhibit the generation of particles caused by the arcing. Although this is not a special condition in the present invention, but is preferred.

The Sb—Te—based alloy sintered compact sputtering target of the present invention may contain, at maximum 20 at %, one or more elements selected from Ag, Au, Pd, Pt, B, Al, Ga, In, Ti, and Zr as additive elements. So as long as the amount is within the foregoing range, in addition to obtaining the intended glass transition temperature, transformation rate and electrical resistance value, it is also possible to minimize the surface defects resulting from the machining process, and the particles can also be effectively inhibited.

Based on the above, it is possible to obtain a sintered compact having a diameter of 380 mm or more and a thickness of 20 mm or less containing a chalcogenide element (A) and a Vb group element (B), or containing a IVb group element (C) and/or additive element (D) added thereto as needed.

Consequently, it is possible to obtain a sintered compact composed of a chalcogenide element (A) and a Vb group element (B) or a sintered compact composed of a chalcogenide element (A), a Vb group element (B) and one or more elements from a IVb group element (C) and/or additive element (D), having a sintered structure in which the average grain size is 50 μm or less, the deflecting strength is 40 MPa or more, the relative density is 99% or higher, and the standard deviation of the in-plane density of the sintered compact surface is less than 1%.

The sputtering target produced from the sintered compact obtained as described can considerably reduce defects such as micropores, is free from cracks even when it is bonded to a backing plate, and yields a superior effect of maintaining the warping within a tolerable range.

As described above, the sintered compact sputtering target is free from defects such as micropores, and a target having a uniform fine crystal structure will have reduced surface irregularities caused by sputter erosion and yield a half-mirror appearance, is free from a crater-shaped abnormal structure, and is able to effectively inhibit the generation of particles caused by the redeposited film on the target surface peeling off. Thus, it is possible to effectively inhibit the generation of particles, abnormal discharge, and nodules in the foregoing sputtering process.

With the sputtering target of the present invention, it is possible to make the content of oxygen to be 2000 ppm or less, in particular 1000 ppm or less, and even 500 ppm or less. The reduction of oxygen is effective in further reducing the generation of particles and the generation of abnormal discharge.

### EXAMPLES

The present invention is now explained in detail with reference to the Examples. These Examples are merely illustrative, and the present invention shall in no way be limited thereby. In other words, various modifications and other embodiments based on the technical spirit claimed in the claims shall be included in the present invention as a matter of course.

### Example 1

The respective raw material powders of Te, Sb and Ge respectively having a purity of 99.995 (4N5) excluding gas components were melted to obtain a composition of Ge₂₂Sb₂₂Te₅₆, and slowly cooled in a furnace to prepare a cast ingot. The raw materials of the respective elements were subject to acid cleaning and deionized water cleaning prior to the melting process in order to sufficiently eliminate impurities remaining on the surface.

Consequently, a high purity Ge₂₂Sb₂₂Te₅₆ ingot maintaining a purity 99.995 (4N5) was obtained. Subsequently, the high purity Ge₂₂Sb₂₂Te₅₆ ingot was pulverized with a ball mill in an inert atmosphere to prepare raw material powder having an average grain size of approximately 30 μm, and a maximum grain size of approximately 90 μm (one digit of the grain size was rounded off).

Subsequently, the raw material powder was filled in a graphite die having a diameter of 400 mm, and subject to the following conditions in an inert atmosphere; namely, a final rise temperature of 600° C. at a temperature rise rate of 5° C./min, and a final pressing pressure of 150 kgf/cm². Further, as a result of controlling the hot press pressurization pattern to satisfy, with respect to the temperature, the conditions of the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), a Ge₂₂Sb₂₂Te₅₆ intermediate sintered compact was prepared.

In the foregoing case, for instance, based on the foregoing formula, the pressing pressure was strictly adjusted to P≦20 kgf/cm² since this will be P (kgf/cm²)≦{150 (kgf/cm²)/(600° C.−25° C.)}×(100° C.−25°C.) +1 (kgf/cm²) at a heating temperature of 100° C. Similarly, the pressing pressure was strictly adjusted to P≦45 kgf/cm² at a heating temperature of 200° C., and to P≦72 kgf/cm² at a heating temperature of 300° C. in order to achieve the hot press pressurization pattern according to the foregoing formula.

Specifically, the pressing pressure was set to P=0 kgf/cm² at the heating temperature of less than 100° C., to the pressing pressure of P=20 kgf/cm² at the heating temperature of 100 to less than 200° C., to the pressing pressure of P=45 kgf/c cm² at the heating temperature of 200 to less than 300° C., to the pressing pressure of P=72 kgf/cm² at the heating temperature of 300 to less than the final rise temperature of 600° C., and to the pressing pressure of P=150 kgf/cm² at the heating temperature of 600° C.

Incidentally, since the pressing pressure can be gradually increased as described above pursuant to the increase in the heating temperature, the final pressing pressure will reach 150 kgf/cm² more quickly. Thus, it can be said that the production time efficiency can be shortened and the production efficiency can be improved by just that much. Nevertheless, an absolute condition is not to deviate from the foregoing formula. Moreover, the sintered compact was retained for 2 hours after reaching the final rise temperature and the final pressing pressure.

HIP treatment was further performed to the obtained intermediate sintered compact having a diameter of 400 mm under the condition of P_{HIP}=750 to 2000 kgf/cm². Specifically, HIP treatment was performed under the following five types of conditions; namely, P_{HIP}=750 kgf/cm², P_{HIP}=900 kgf/cm², P_{HIP}=1000 kgf/cm², P_{HIP}=1500 kgf/cm², and P_{HIP}=2000 kgf/cm².

The target shown in FIG. 1 is an example of P_{HIP}=1000 kgf/cm², and is the structure of a target that used standard pulverized powder, and had a crystal grain size of 30 μm or less.

With FIG. 3 corresponding to Comparative Example 1 described later, at the hot press stage, 5 micropores (micropores having an average diameter of 0.1 to 1 μm) were observed at the grain boundary. This corresponds to approximately 500 micropores in an area of 40000 μm².

Subsequently, the obtained final sintered compact was subject to cutting work in order to prepare a target. Based on the foregoing HIP treatment, nearly all of the micropores were eliminated. The results are shown in FIG. 1. This is a 5000× microphotograph upon observing the structure of the target.

Specifically, as shown in FIG. 1, the number of micropores having an average diameter of less than 1 μm existing in an area of 40000 μm² on the target surface was 0. Pores having an average diameter of 1 μm or more did not exist at all.

Although this result is based on a representative example of performing the HIP treatment at P_{HIP}=1000 kgf/cm², even with the targets that were subject to the HIP treatment based on the other four conditions, the number of micropores having an average diameter of less than 1 μm existing in an area of 40000 μm² on the target surface was also 0. Pores having an average diameter of 1 μm or more did not exist at all.

Thus, it was discovered that the two-stage sintering for which appropriate conditions were set is extremely effective in eliminating the micropores.

Moreover, in order to measure the density, the measurement was performed upon sampling from 9 locations in a cross shape. This average value was defined as the sintered compact density. The average value of the deflecting strength was measured by sampling from the middle of the center and the radial direction, and three locations in the peripheral vicinity, and this average value was defined as the deflecting strength.

The average grain size of the sintered compact was calculated from the result of observing the structure of 9 locations in a cross shape. Consequently, in Example 1, the relative density of the sintered compact was 99.8%, the standard deviation of the variation in the density was <1%, the deflecting strength was 61 MPa, and, with respect to the composition of the respective crystal grains, Ge was within the range of 17.8 to 26.6 at % and Sb was within the range of 17.8 to 26.6 at % (±20%), the average grain size of the sintered compact was 36 μm and the maximum grain size was 90 μm, and a favorable sintered compact was obtained.

Using similar methods, favorable bonding properties have been confirmed regardless of the type of backing plate; regardless of whether they are formed from copper alloy or aluminum alloy.

Subsequently, the target surface was observed, but no macro pattern could be found across the entire target.

Sputtering was performed using this target, and this target had an extremely low particle generation rate of 18 particles or less compared to a conventional high quality, high density small-sized target (diameter 280 mm). In addition, there was no occurrence of grain dropping or generation of nodules caused by micropores during sputtering.

### Example 2

In addition to the conditions of Example 1, additional pulverization was performed using a jet mill. The sintering conditions using this powder; that is, the sintering conditions of the vacuum hot press and HIP were the same as Example 1. The structure of the target using the jet mill powder is shown in FIG. 2.

As shown in FIG. 2, as with Example 1, micropores having an average diameter of less than 1 μm existing in an area of 40000 μm² on the target surface could not be acknowledged at all.

It was possible to obtain a sintered compact having composition uniformity in which Ge is within the range 21.1 to 23.3 at % and Sb is within the range of 21.1 to 23.3 at % (±5%), average crystal grain size was 2.2 μm and maximum grain size was 8 μm yielding an ultrafine structure, oxygen concentration was 1900 ppm, relative density was 99.8%, standard deviation in the variation of the density was <1%, and deflecting strength was 90 MPa.

### Example 3

Ag, In, Sb, Te powder raw materials respectively having a purity of 4N5 excluding gas components were used and blended to achieve a Ag₅In₅Sb₇₀Te₂₀ alloy, and, under the same sintering conditions as Example 1; that is, based on vacuum hot press and HIP, a sintered compact having a purity of 4N5 and a composition of Ag₅In₅Sb₇₀Te₂₀ was obtained. Specifically, excluding the component composition, a sintered compact was prepared in the same conditions of Example 1.

Microspores were examined in the sintered compact having a diameter of 400 mm that was prepared in Example 3. Consequently, nearly all of the micropores were eliminated. After HIP, the number of micropores having an average diameter of less than 1 μm existing in an area of 40000 μm² on the target surface was also 0. Moreover, pores having an average diameter of 1 μm or more did not exist at all either. As described above, it was discovered that the two-stage sintering for which appropriate conditions were set is extremely effective in eliminating the micropores.

Moreover, for measuring the density, the measurement was performed upon sampling from 9 locations in a cross shape. This average value was defined as the sintered compact density. The average value of the deflecting strength was measured by sampling from the middle of the center and the radial direction, and three locations in the peripheral vicinity, and this average value was defined as the deflecting strength. The average grain size of the sintered compact was calculated from the result of observing the structure of 9 locations in a cross shape.

Consequently, in Example 3, the relative density of the sintered compact was 99.8%, the standard deviation of the variation in the density was <1%, the deflecting strength was 51 MPa, and the average grain size of the sintered compact was 38 μm, and a favorable sintered compact was obtained. There was no occurrence of grain dropping or generation of nodules caused by micropores during sputtering.

Although not shown in the Examples, the sintered compacts and the targets produced therefrom containing other chalcogenide elements (A) and Vb group elements (B), or containing other IVb group elements (C) or additive elements (D) added thereto were all favorable sintered compacts as with Example 1 and Example 2, in which the relative density of the sintered compact was 99.8% or higher, standard deviation in the variation of the density was <1%, deflecting strength was 60 MPa or more, and average grain size of the sintered compact was 36 μm or less.

Moreover, warping after the bonding could not be acknowledged at all, and there were no cracks after the bonding. In addition, though the macro pattern was observed in the polishing process, no macro pattern could be found across the entire target. Sputtering was performed using this target, and this target showed a particle generation rate that is equal to or less than a conventional high quality, high density small-sized target (diameter 280 mm).

### Comparative Example 1

The respective raw material powders of Te, Sb and Ge respectively having a purity of 99.995 (4N5) excluding gas components were melted to obtain a composition of Ge₂₂Sb₂₂Te₅₆, and prepare a cast ingot. The raw materials of the respective elements were subject to acid cleaning and deionized water cleaning prior to the melting process to sufficiently eliminate impurities remaining on the surface.

Consequently, a high purity Ge₂₂Sb₂₂Te₅₆ ingot maintaining a purity 99.995 (4N5) was obtained. Subsequently, the high purity Ge₂₂Sb₂₂Te₅₆ ingot was pulverized with a ball mill in an inert atmosphere to prepare raw material powder having an average grain size of approximately 30 μm, and a maximum grain size of approximately 90 μm (one digit of the grain size was rounded off). The foregoing conditions are the same as Example 1.

Subsequently, the raw material powder was filled in a graphite die having a diameter of 400 mm, and subject to the following conditions in an inert atmosphere; namely, a final rise temperature of 600° C. at a temperature rise rate of 15° C./min, and a final pressing pressure of 150 kgf/cm². Further, as a result of controlling the hot press pressurization pattern to satisfy, with respect to the temperature, the conditions of the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), a Ge₂₂Sb₂₂Te₅₆ sintered compact was prepared. HIP was not performed. The structure of the target prepared based on the foregoing conditions is shown in FIG. 3. As shown in FIG. 3, micropores can be observed at the crystal grain boundary.

### Comparative Example 2

The raw material powder obtained in Comparative Example 1 was filled in a graphite die having a diameter of 400 mm, and subject to the following conditions in an inert atmosphere; namely, a final rise temperature of 450° C. at a temperature rise rate of 5° C./min, and a final pressing pressure of 150 kgf/cm². Further, as a result of controlling the hot press pressurization pattern to satisfy, with respect to the temperature, the conditions of the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), a sintered compact was prepared. HIP was not performed.

### Comparative Example 3

The raw material powder obtained in Comparative Example 1 was filled in a graphite die having a diameter of 400 mm, and subject to the following conditions in an inert atmosphere; namely, a final rise temperature of 600° C. at a temperature rise rate of 5° C./min, and a final pressing pressure of 80 kgf/cm². Further, as a result of controlling the hot press pressurization pattern to satisfy, with respect to the temperature, the conditions of the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), a sintered compact was prepared. HIP was not performed.

### Comparative Example 4

The raw material powder obtained in Comparative Example 1 was filled in a graphite die having a diameter of 400 mm, and subject to the following conditions in an inert atmosphere; namely, a final rise temperature of 600° C. at a temperature rise rate of 5° C./min, and a final pressing pressure of 150 kgf/cm². Further, as a result of controlling the hot press pressurization pattern outside the conditions of the following formula: P(pressure)≦{Pf/(Tf−T₀)}×(T−T₀)+P₀ (Pf: final pressure, Tf: final temperature, P₀: atmospheric pressure, T: heating temperature, T₀: room temperature, and temperatures in Celsius), a sintered compact was prepared.

As the condition outside the foregoing formula, the pressing pressure was raised to P=75 kgf/cm² at the stage when the heating temperature was 100° C. in order to accelerate the pressurization process. HIP was not performed.

As described above, with the conditions of the present invention, based on the foregoing formula, the pressing pressure was strictly adjusted to PS≦20 kgf/cm² since this will be P≦150 (kgf/cm²)/600° C.×100° C. at a heating temperature of 100° C. Similarly, the pressing pressure was strictly adjusted to PS≦45 kgf/cm² at a heating temperature of 200° C. and to P≦72 kgf/cm² at a heating temperature of 300° C. in order to achieve the hot press pressurization pattern according to the foregoing formula. However, the condition of accelerating the pressurization process by raising the pressing pressure to P=72 kgf/cm² deviates from the conditions of the present invention. In addition, this production method clearly differs from the present invention with respect to the point that HIP was not performed.

### Comparative Example 5

In addition to the conditions of Example 1, additional pulverization was performed using a jet mill. The sintering conditions using this powder; that is, the sintering conditions of the vacuum hot press and HIP were the same as Example 1. Nevertheless, the sintered compact was produced without performing HIP, and the conditions are for comparison with Example 2. The composition was as follows; Ge was within the range of 21.1 to 23.3 at %, and Sb was within the range of 21.1 to 23.3 at % (±5%).

With the obtained sintered compact, the average crystal grain size was 2.2 μm, maximum grain size was μm, oxygen concentration was 1900 ppm, relative density of the sintered compact was 99.8%, standard deviation in the variation of the density was <1%, and deflecting strength was 75MPa.

The structure of the target prepared with this production method is shown in FIG. 4. As shown in FIG. 4, numerous micropores were observed.

In order to measure the density of the sintered compact having a diameter of 400 mm obtained in Comparative Examples 1 to 5, the measurement was performed upon sampling from 9 locations in a cross shape. This average value was defined as the sintered compact density. The average value of the deflecting strength was measured by sampling from the middle of the center and the radial direction, and three locations in the peripheral vicinity, and this average value was defined as the deflecting strength. The average grain size of the sintered compact was calculated from the result of observing the structure of 9 locations in a cross shape. These measurement conditions are the same as Example 1.

Consequently, in Comparative Example 1, the relative density of the sintered compact was 98.5%, the standard deviation of the variation in the density was 3%, the deflecting strength was 32 MPa, and the average grain size of the sintered compact was 42 μm, and a fragile sintered compact was obtained. The number of micropores having an average diameter of less than 1 μm existing in an area of 40000 μm² on the target surface was numerous at 500 micropores.

Similarly, in Comparative Example 2, the relative density of the sintered compact was 94%, the standard deviation of the variation in the density was 1%, the deflecting strength was 26 MPa, and the average grain size of the sintered compact was 35 μm, and a fragile sintered compact was obtained. The number of micropores having an average diameter of less than 1 μm existing in an area of 40000 μm² on the target surface was numerous at 1000 micropores.

Similarly, in Comparative Example 3, the relative density of the sintered compact was 96.1%, the standard deviation of the variation in the density was 1%, the deflecting strength was 29 MPa, and the average grain size of the sintered compact was 39 μm, and a fragile sintered compact was obtained. The number of micropores having an average diameter of less than 1 μm existing in an area of 40000 μm² on the target surface was numerous at 1500 micropores.

Similarly, in Comparative Example 4, the relative density of the sintered compact was 99.2%, the standard deviation of the variation in the density was 1%, the deflecting strength was 38 MPa, and the average grain size of the sintered compact was 42 μm, and a fragile sintered compact was obtained. The number of micropores having an average diameter of less than 1 μm existing in an area of 40000 μm² on the target surface was numerous at 1200 micropores.

Similarly, in Comparative Example 5, the relative density of the sintered compact was 99.2%, the standard deviation of the variation in the density was 1%, the deflecting strength was 75 MPa, and the average grain size of the sintered compact was 42 μm, and a fragile sintered compact was obtained compared to Example 2. The number of micropores having an average diameter of less than 1 μm existing in an area of 40000 μm² on the target surface was large at 7000 micropores.

The sintered compacts prepared in Comparative Example 1 to 5 were respectively bonded to a copper alloy backing plate using indium so that the bonding thickness would become 0.4 to 1.4 mm according to the same process as Example 1. Subsequently, a target plate was prepared by performing cutting work.

Consequently, warping occurred and some cracks were observed after bonding, and a macro pattern was observed in some parts of the target.

Sputtering was performed using this target, but the particle generation rate was significantly high at 300 to thousands of particles, and was far lower than a practically applicable level.

### INDUSTRIAL APPLICABILITY

The present invention discovered that defects of micropores and the like are a major cause of the generation of particles, and offers a method of considerably reducing the defects of such micropores from the sintered compact target. The present invention is able to significantly reduce defects of micropores and the like by improving the production process.

Since the sintered compact having the composition of the present invention is extremely fragile, if a large diameter sputtering target is prepared and this is bonded with a backing plate, there was a problem in that cracks would occur on the target surface or the target itself would crack due to the difference in thermal expansion. Nevertheless, the present invention is able to produce a high strength, high density and large diameter sintered compact or sputtering target.

Accordingly, upon forming a thin film of a Ge—Sb—Te material or the like as a phase change recording material; that is, as a medium for recording information by using phase transformation, it will be possible to use a larger sputtering target and improve the quality of deposition, and the present invention yields superior effects of improving the production efficiency, and producing a uniform phase change recording material.

1. A sintered compact target containing an element (A) and an element (B), wherein the sintered compact target is free from pores having an average diameter of 1 μm or more, and the number of micropores having an average diameter of 0.1 to 1 μm existing in an area of 40000 μm² of the target surface at random check is 100 micropores or less, wherein (A): one or more chalcogenide elements selected from S, Se, and Te; and (B): one or more Vb group elements selected from Bi, Sb, As, P, and N.

2. A sintered compact target containing an element (A), an element (B) and one or more elements selected from (C) or (D), wherein the sintered compact target is free from pores having an average diameter of 1 μm or more, and the number of micropores having an average diameter of 0.1 to 1 μm existing in an arbitrarily selected area of 40000 μm² of the target surface at random check is 100 micropores or less, wherein (A): one or more chalcogenide elements selected from S, Se, and Te; (B): one or more Vb group elements selected from Bi, Sb, As, P, and N; (C): one or more IVb group elements selected from Pb, Sn, Ge, Si, and C; and (D): one or more elements selected from Ag, Au, Pd, Pt, B, Al, Ga, In, Ti, and Zr.

3. The sintered compact target according to claim 2, wherein the element (A) is Te, the element (B) is Sb, the element (C) is Ge, and the element (D) is one or more elements selected from Ag, Ga, and In.

4. The sintered compact target according to claim 3, wherein the sintered compact is selected from the group consisting of Ge—Sb—Te, Ag—In—Sb—Te, and Ge—In—Sb—Te.

5. The sintered compact target according to claim 2, wherein the average crystal grain size of the structure of the sintered compact target is 50 μm or less, the deflecting strength is 40 MPa or more, the relative density is 99% or higher, the standard deviation of the relative density is 1%, and the variation in the composition of the respective crystal grains configuring the target is less than ±20% of the overall average composition.

6. The sintered compact target according to claim 5, wherein the average crystal grain size is 10 μm or less.

7. A method of producing a sintered compact containing an element (A) and an element (B), including the steps of mixing raw material powder composed of the respective elements or raw material powder of an alloy of two or more elements, and vacuum hot press the mixed powder under conditions that satisfy the following formula: P(pressure)≦{Pf/(Tf−T₀)}×(T−T₀)+P₀ [(] wherein Pf: final pressure, Tf: final temperature, P₀: atmospheric pressure, T: heating temperature, T₀: room temperature. and temperatures are in Celsius[)], and further performing HIP treatment under the conditions of Pₕᵢₚ>5×Pf, wherein the sintered compact is free from pores having an average diameter of 1 μm or more, and the number of micropores having an average diameter of less than 1 μm existing in an area of 40000 μm² of the target surface is 100 micropores or less, and wherein (A): one or more chalcogenide elements selected from S, Se, and Te and (B): one or more Vb group elements selected from Bi, Sb, As, P, and N.

8. A method of producing a sintered compact containing an element (A), an element (B) and one or more elements selected from (C) or (D), including the steps of mixing raw material powder composed of the respective elements or raw material powder of an alloy of two or more elements, and vacuum hot press the mixed powder under conditions that satisfy the following formula: P(pressure)≦{Pf/(Tf−T₀)}×(T−T₀)+P₀ [(] wherein Pf: final pressure, Tf: final temperature, P₀: atmospheric pressure, T: heating temperature, T₀: room temperature, and temperatures are in Celsius[)], and further performing HIP treatment under the conditions of Pₕᵢₚ5×Pf, wherein the sintered compact is free from pores having an average diameter of 1 μm or more, and the number of micropores having an average diameter of 0.1 to 1 μm existing in an area of 40000 μm² of the target surface is 100 micropores or less[:] and wherein (A): one or more chalcogenide elements selected from S, Se, and Te; (B): one or more Vb group elements selected from Bi, Sb, As, P, and N; (C): one or more IVb group elements selected from Pb, Sn, Ge, Si, and C; and (D): one or more elements selected from Ag, Au, Pd, Pt, B, Al, Ga, In, Ti, and Zr.

9. The method of producing a sintered compact according to claim 8, wherein sintering is performed by using raw material powder in which the element (A) is Te, the element (B) is Sb, the element (C) is Ge, and the element (D) is one or more elements selected from Ag, Ga, and In.

10. The method of producing a sintered compact according to claim 9, wherein the sintered compact is selected from the group consisting of Ge—Sb—Te, Ag—In—Sb—Te, and Ge—In—Sb—Te.

11. The method of producing a sintered compact according to claim 8, wherein sintering is performed by using raw material powder of elements constituting the sintered compact in which the raw material powder is composed of an alloy, a compound or a mixture of constituent elementary substances or constituent elements, and the average grain size is 0.1 μm to 50 μm, the maximum grain size is 90 μm or less, and the purity is 4N or higher.

12. The method of producing a sintered compact according to claim 8, wherein, in the course of heating temperature T rising from 100 to 500° C. during the hot press, the pressure is maintained at a constant level for 10 to 120 minutes at least in a part of the heating temperature range.

13. The method of producing a sintered compact according to claim 7, wherein the sintered compact is selected from the group consisting of Ge—Sb—Te, Ag—In—Sb—Te, and Ge—In—Sb—Te.

14. The method of producing a sintered compact according to claim 7, wherein sintering is performed by using raw material powder of elements constituting the sintered compact in which the raw material powder is composed of an alloy, a compound or a mixture of constituent elementary substances or constituent elements, and the average grain size is 0.1 μm to 50 μm, the maximum grain size is 90 μm or less, and the purity is 4N or higher.

15. The method of producing a sintered compact according to claim 7, wherein, in the course of heating temperature T rising from 100 to 500° C. during the hot press, the pressure is maintained at a constant level for 10 to 120 minutes at least in a part of the heating temperature range.

16. The sintered compact target according to claim 1, wherein the sintered compact is selected from the group consisting of Ge—Sb—Te, Ag—In—Sb—Te, and Ge—In—Sb—Te.

17. The sintered compact target according to claim 1, wherein the average crystal grain size of the structure of the sintered compact target is 50 μm or less, the deflecting strength is 40 MPa or more, the relative density is 99% or higher, the standard deviation of the relative density is 1%, and the variation in the composition of the respective crystal grains configuring the target is less than ±20% of the overall average composition.

18. The sintered compact target according to claim 17, wherein the average crystal grain size is 10 μm or less.
